(19) United States
(12) Patent Application Publication
(10) Pub. No.: US 2012/0288800 A1
(43) Pub. Date: Nov. 15, 2012

(54) ELECTRON BEAM DRAWING APPARATUS AND METHOD OF MANUFACTURING DEVICE

(75) Inventor: Jun ITO, Utsunomiya-shi (JP)

(73) Assignee: CANON KABUSHIKI KAISHA, Tokyo (JP)

(21) Appl. No.: 13/462,088

(22) Filed: May 2, 2012

(30) Foreign Application Priority Data
May 9, 2011 (JP) 2011-104740

(51) Int. Cl. G03F 7/20; H01J 3/02

(52) U.S. Cl. 430/296; 250/492.3

(57) ABSTRACT

An electron beam drawing apparatus performs drawing on a substrate with an electron beam emitted by an electron gun. The apparatus includes a conditioning chamber configured to perform conditioning of a spare electrode that is a spare for an electrode which constitutes the electron gun, and a driving mechanism configured to remove a used electrode from the electron gun, and to install, into the electron gun, the spare electrode having been subjected to the conditioning, wherein the conditioning includes supplying of electric power to the spare electrode.

### BACKGROUND OF THE INVENTION

1. Field of the Invention

The present invention relates to an electron beam drawing apparatus and a method of manufacturing a device.

2. Description of the Related Art

In the mass production stage of semiconductor devices, an optical stepper having a high productivity has been employed. In producing, for example, memory devices in generations subsequent to a 4G DRAM having a line width of 0.1 μm or less, an electron beam drawing apparatus (to be also referred to as an electron beam lithography apparatus hereinafter) having a high resolution and an excellent productivity is available as one of apparatuses which replace light exposure apparatuses.

To achieve a high throughput, an electron gun of an electron beam drawing apparatus requires a current having, for example, a luminance of 2.0×10⁶ A/cm²sr and an emittance of about 15 to 30 μm·mrad. However, when the electron gun is used at such a high current, a cathode electrode has a temperature as high as 1,800 K or more, so its life shortens. To maintain a desired performance, the cathode electrode requires periodical replacement at a high frequency. This lowers the operating ratio of the electron beam drawing apparatus, thus leading to an increase in cost of manufactured devices. Hence, various proposals to shorten the time required for cathode electrode replacement have been presented.

In an example of these related art techniques, a new cathode electrode is accommodated in a spare exhaust chamber, and the spare exhaust chamber is evacuated into a vacuum. In replacing a cathode electrode, a gate valve is opened to unload a used cathode electrode from an electron gun chamber into the spare exhaust chamber and load a new cathode electrode from the spare exhaust chamber into the electron gun chamber, and the gate valve is closed. The electron gun chamber is then evacuated into a vacuum to restart the operation. Note that the used cathode electrode can also be removed from an opening in the spare exhaust chamber. According to this embodiment, the interior of the electron gun chamber is not open to the atmosphere, thus making it possible to restart the operation immediately after replacement of the cathode electrode. Also, even if the electron gun chamber must be evacuated into a high vacuum after replacement of the cathode electrode, this can be done in a very short period of time (Japanese Patent Laid-Open No. 4-292841).

Unfortunately, the electron gun is known to readily generate abnormal discharge immediately after replacement of the cathode electrode. This results from the influence of, for example, a foreign substance adhering on a component such as the replaced cathode electrode or a filament or damage to this component. This means that in the initial stage of applying a high rated voltage to normally output a beam, an electric field concentrates on the portion with damage or a foreign substance, so this portion causes a dielectric breakdown and, in turn, generates abnormal discharge in large amounts. To avoid this, after the part or whole of an electron beam emitting portion of the electron gun is replaced or maintained, a high voltage is applied to the electron gun in an evacuated state, thereby performing electrode burning and conditioning processing to improve the voltage resistance performance (Japanese Patent Laid-Open No. 2005-026112 (paragraph 0008, FIG. 8)).

However, it takes a long period of time to perform conditioning such as burning and conditioning of the cathode electrode in the vacuum chamber, and no pattern can be drawn on the substrate during this conditioning. Hence, a considerable time is required until the electron beam drawing apparatus becomes ready for drawing processing on the substrate.

### SUMMARY OF THE INVENTION

The present invention provides, for example, a technique advantageous in reduction of time required to replace an electrode of an electron gun.

One of the aspects of the present invention provides an electron beam drawing apparatus which includes an electron gun, and performs drawing on a substrate with an electron beam emitted by the electron gun, the apparatus comprising: a conditioning chamber configured to perform conditioning of a spare electrode that is a spare for an electrode which constitutes the electron gun; and a driving mechanism configured to remove a used electrode from the electron gun, and to install, into the electron gun, the spare electrode having been subjected to the conditioning, wherein the conditioning includes supplying of electric power to the spare electrode.

Further features of the present invention will become apparent from the following description of exemplary embodiments with reference to the attached drawings.

### BRIEF DESCRIPTION OF THE DRAWINGS

FIG. 1 is a view showing the configuration of an electron beam drawing apparatus according to the first embodiment of the present invention;

FIG. 2 is a flowchart showing the operation of the electron beam drawing apparatus according to the first embodiment of the present invention;

FIG. 3 is a flowchart showing the operation of the electron beam drawing apparatus according to the first embodiment of the present invention;

FIG. 4 is a flowchart showing the operation of the electron beam drawing apparatus according to the first embodiment of the present invention; and

FIG. 5 is a view showing the configuration of an electron beam drawing apparatus according to the second embodiment of the present invention.

### DESCRIPTION OF THE EMBODIMENTS

Embodiments of the present invention will be described below with reference to the accompanying drawings.

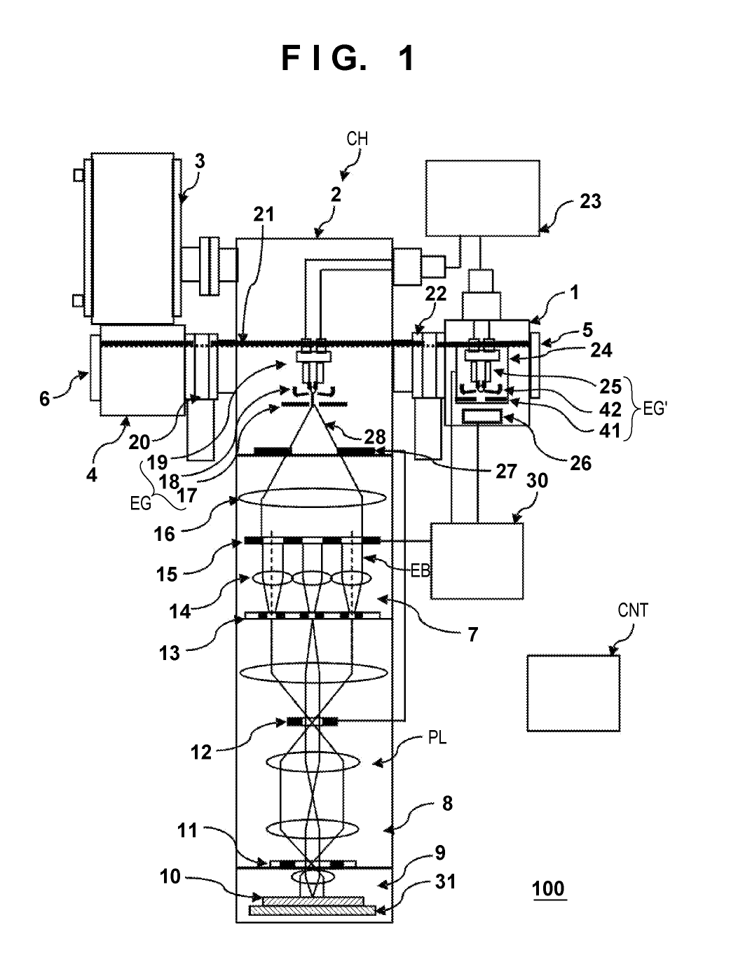

The configuration of an electron beam drawing apparatus 100 according to the first embodiment of the present invention will be described with reference to FIG. 1. Although an electron beam drawing apparatus which draws a pattern on a substrate 10 using a plurality of electron beams will be taken as an example herein, the use of a plurality of electron beams is not essential, and the present invention is also applicable to an electron beam drawing apparatus which draws a pattern on the substrate 10 using a single electron beam.

The electron beam drawing apparatus 100 is configured to draw a pattern on the substrate 10 using an electron beam to form a latent image on the substrate 10 in a chamber CH which isolates the internal space from the external space. The chamber CH can include, for example, an electron gun chamber 2, device chamber 7, projection system chamber 8, and stage chamber 9. The electron gun chamber 2 accommodates an electron gun EG. The device chamber 7 accommodates a blanking array 13, lens array 14, aperture array 15, and collimator lens 16. The projection system chamber 8 accommodates a projection system PL. The stage chamber 9 accommodates a stage 31.

The electron gun chamber 2 is connected to an ion pump 3, and is set to a degree of vacuum of, for example, about 5.0×10⁻⁷ to 2.0×10⁻⁶ Pa while the substrate 10 is irradiated with no electron beam. Although not shown in FIG. 1, the other chambers 7, 8, and 9 are connected to vacuum pumps, and can be vacuumed to a pressure on the order of about, for example, 10⁻⁵ Pa.

The electron gun EG includes three electrodes: a cathode electrode 19, a Wehnelt electrode 18, and an anode electrode 17. The electron gun EG emits thermoelectrons from the cathode electrode 19 as the cathode electrode 19 is heated to about 1,700 K to 1,900 K by a current supplied from a power supply 23. Of an electron beam 28 radially emitted by the electron gun EG, a component unnecessary for drawing is blocked by a blocking electrode 27. The electron beam 28 is shaped into a beam having a desired size by an electrostatic lens (not shown) and the collimator lens 16, and almost perpendicularly enters the aperture array 15. The aperture array 15 is a plate including a plurality of apertures. A plurality of electron beams EB are generated by the aperture array 15, and individually converged on the blanking array 13 by the lens array 14.

The blanking array 13 is an array of deflectors serving as blankers, and individually deflects the plurality of electron beams EB in accordance with the pattern to be drawn. An electron beam 28 that is deflected by the blanking array 13 is blocked by a blanking aperture 12, and an electron beam 28 that is not deflected by the blanking array 13 is converged by the projection system PL and guided onto the substrate 10 on the stage 31.

When the electron beam drawing apparatus 100 continues to draw a pattern on the substrate 10, the distal end of the cathode electrode 19 of the electron gun EG gradually sublimates, so the shape of the cathode electrode 19 changes. This hinders the illuminance of the electron beam from reaching that corresponding to a desired energy, so the life of the electron gun EG comes to an end. This end of life results from factors associated with the use temperature and use environment of the cathode electrode 19 and the shape of the electrode material. When the electrode material is, for example, LaB₆ (lanthanum hexaboride), the life of the electron gun EG is about 1,000 to 2,000 hrs.

The electron beam drawing apparatus 100 includes a conditioning chamber 1 for preparing a cathode electrode (spare electrode) 25 as a spare for the cathode electrode 19, and a removal chamber 4 for removing the cathode electrode 19 the life of which has come to an end. In the first embodiment, the conditioning chamber 1 is disposed outside the electron gun chamber 2.

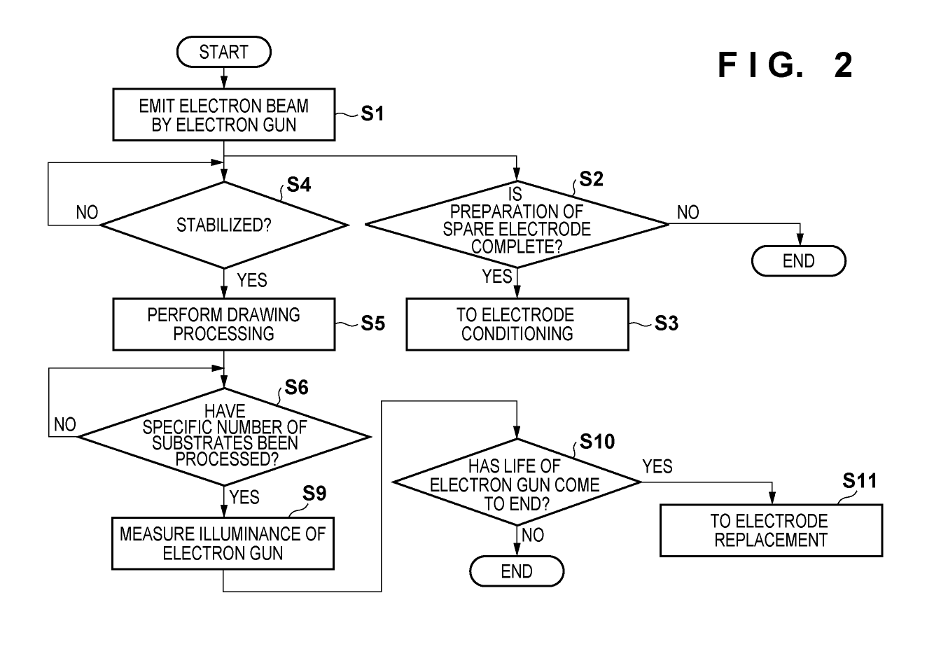

The operation of the electron beam drawing apparatus 100 will be exemplified below with reference to FIG. 1 and a flowchart shown in FIG. 2. The electron beam drawing apparatus 100 includes a controller CNT which controls the following operation.

In step S1, to draw a pattern on the substrate 10, the controller CNT causes the electron gun EG to start emitting an electron beam. In step S4, the controller CNT waits until the illuminance of the electron beam emitted by the electron gun EG stabilizes. In this stage, the blanking array 13 deflects the electron beams EB so they are not guided onto the substrate 10, that is, they are blocked by the blanking aperture 12. Although not shown in FIG. 1, whether or not the illuminance of the electron beam from the electron gun EG has stabilized can be checked, using an electron detector (for example, a photodiode or a Faraday cup) disposed on the side of the electron gun EG with respect to the blanking aperture 12.

The controller CNT can execute step S2 at an arbitrary timing such as a timing before or immediately after step S1, or a timing at which a pattern is being or having been drawn on the substrate 10. Step S2 may also be executed when the cathode electrode 19 used at the current moment has deteriorated to a predetermined degree. This deterioration can be determined based on the result of diagnostic imaging of the cathode electrode 19 or on the cumulative use time of the cathode electrode 19.

In step S2, the controller CNT checks whether preparation of the spare cathode electrode 25 is appropriately complete. If preparation of the spare cathode electrode 25 is appropriately complete, the processes in step S2 and subsequent steps end. On the other hand, if preparation of the spare cathode electrode 25 is not appropriately complete, the controller CNT executes step S3 (preparation of the spare cathode electrode 25). Step S3 (preparation of the spare cathode electrode 25) will be described in detail later.

If it is determined in step S4 that the illuminance of the electron beam from the electron gun EG has stabilized, the controller CNT executes pattern drawing processing on the substrate 10 in step S5. The pattern drawing processing in step S5 can be performed by controlling each blanker of the blanking array 13 in accordance with the pattern data while driving the stage 31 which holds the substrate 10. In step S6, the controller CNT determines whether drawing processing has been performed on a specific number of substrates to determine whether the cathode electrode 19 which is mounted in the electron gun EG and used at the current moment has been used to process the specific number of substrates after the mounting. If it is determined in step S6 that the cathode electrode 19 has been used to process the specific number of substrates, the controller CNT executes step S9.

In step S9, the controller CNT uses the above-mentioned electron detector to measure the illuminance of the electron beam emitted by the electron gun EG. In step S10, the controller CNT determines, based on the measurement result obtained in step S9, whether the life of the electron gun EG (the cathode electrode 19 in this case) has come to an end. If it is determined in step S10 that the life of the electron gun EG (cathode electrode 19) has come to an end, the controller CNT replaces the cathode electrode 19 with the prepared, spare cathode electrode 25 in step S11. Step S11 (replacement of the cathode electrode 19) will be described in detail later.

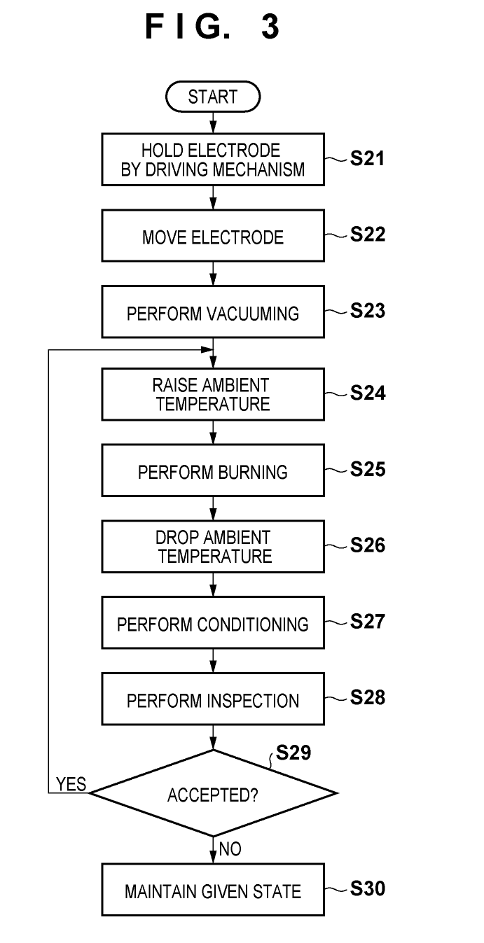

Step S3 (preparation of the spare cathode electrode 25) will be described in detail below with reference to FIG. 3. In step S21, a valve 5 of the conditioning chamber 1 is opened so that a driving mechanism 21 holds the spare cathode electrode 25 and moves it into the conditioning chamber 1. In step S22, the controller CNT moves the spare cathode electrode 25 to a predetermined position in accordance with the movement of the driving mechanism 21. Note that a Wehnelt electrode 42 and an anode electrode 41 are disposed in the conditioning chamber 1, and an electron gun EG′ for conditioning the spare cathode electrode 25 is formed by the spare cathode electrode 25, Wehnelt electrode 42, and anode electrode 41. The predetermined position means a position at which the spare cathode electrode 25 is installed into the electron gun EG′ so that a current can be supplied from the power supply 23 to the spare cathode electrode 25. In step S23, the valve 5 is closed to vacuum the conditioning chamber 1.

When the pressure in the conditioning chamber 1 drops to a predetermined pressure (degree of vacuum) of, for example, 2.0×10⁻⁶ Pa, the controller CNT executes step S24. In step S24, the controller CNT raises the temperature of a surrounding portion 24 which surrounds the electron gun EG′ except for the side in the direction in which the spare cathode electrode 25 is loaded, thereby raising the ambient temperature of the spare cathode electrode 25. The ambient temperature of the spare cathode electrode 25 is raised to a predetermined temperature, for example, a temperature that falls within the range of 130° C. to 150° C. Upon this operation, the spare cathode electrode 25 is heated, so a gas produced upon volatilization of the spare cathode electrode 25 is exhausted. To raise the temperature of the surrounding portion 24, heat generated by electrons that are not used to draw the substrate 10 can be utilized. The blocking electrode 27, aperture array 15, and blanking aperture 12 (an electron optical element which blocks an electron beam) block a large number of electron beams and therefore generate a large amount of heat. In this state, the members which constitute the blocking electrode 27, aperture array 15, and blanking aperture 12 may melt or deform. Hence, the electron beam drawing apparatus 100 includes a cooling device 30 which cools the blocking electrode 27, aperture array 15, and blanking aperture 12. The electron beam drawing apparatus 100 is configured to raise the temperature of the surrounding portion 24 by utilizing heat exhausted by the cooling device 30.

In step S25, the controller CNT burns the spare cathode electrode 25. The spare cathode electrode 25 can be burnt by supplying a current from the power supply 23 to the spare cathode electrode 25. The burning of the spare cathode electrode 25 can be completed at a temperature of, for example, about 150° C. in about 24 to 48 hrs. After the burning is completed, the controller CNT stops raising the temperature (ambient temperature) of the surrounding portion 24 in step S26. Upon this operation, the temperature of the surrounding portion 24 gradually drops, and the degree of vacuum in the conditioning chamber 1 returns to the original degree of vacuum.

When the degree of vacuum in the conditioning chamber 1 becomes that reached in step S23, the controller CNT performs conditioning of the spare cathode electrode 25 in step S27. The conditioning can include, for example, processing of gradually raising the voltage applied to the spare cathode electrode 25 while taking care not to allow the spare cathode electrode 25 to discharge electricity, in accordance with a program. The maximum value of the applied voltage can be, for example, about 1.5 times the voltage used in the electron gun EG. When the spare cathode electrode 25 discharges electricity in the process of raising the voltage applied to it, this voltage is temporarily dropped and raised again. If the number of times of discharge exceeds a predetermined number of times, a conditioning error occurs. In this case, it is determined that the spare cathode electrode 25 has an initial failure, so the process returns to the start of the electrode conditioning sequence, and the spare cathode electrode 25 is replaced with a new cathode electrode 25. Note that burning and conditioning of the spare cathode electrode 25 are common in terms of supplying electric power from the power supply 23 to the spare cathode electrode 25, and can both fall into the concept of the conditioning of the spare cathode electrode 25.

After the end of step S27 (conditioning), the controller CNT inspects in step S28 whether the conditioning of the spare cathode electrode 25 is appropriately complete, using an inspection unit 26 disposed in the conditioning chamber 1. The inspection items can include, for example, the illuminance of an electron beam emitted by the electron gun EG′ including the spare cathode electrode 25, and the shape of the spare cathode electrode 25. If the spare cathode electrode 25 is rejected as a result of inspection, the controller CNT returns the process to step S24, in which it retries inspection; or returns the process to step S21, in which it conditions a new cathode electrode 25. If the spare cathode electrode 25 is accepted, the controller CNT holds it in the vacuum environment within the conditioning chamber 1 in step S30.

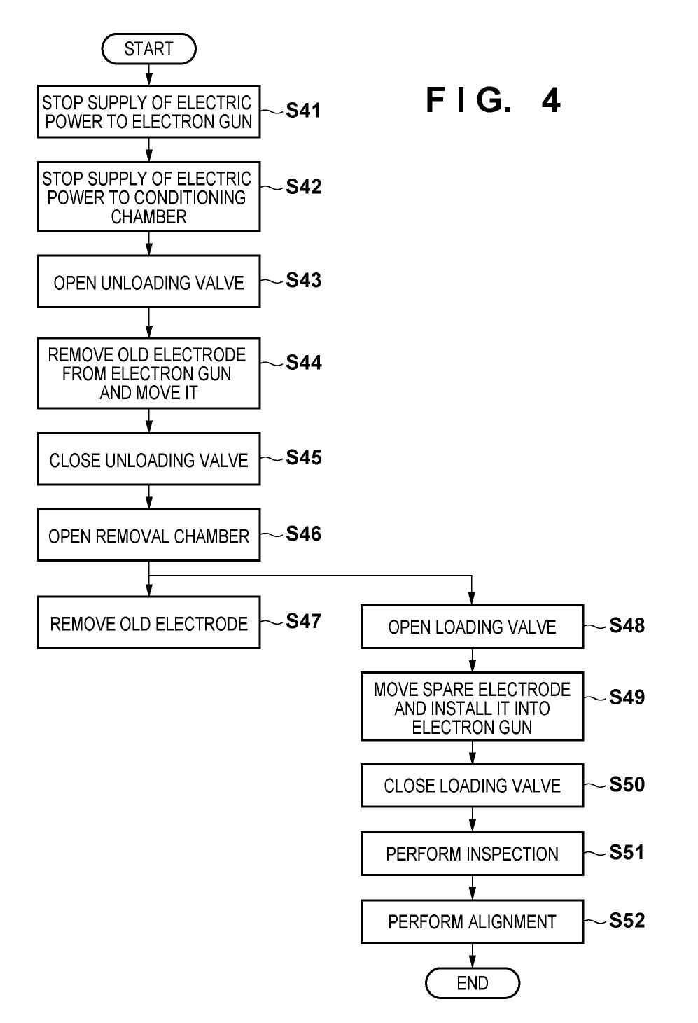

Step S11 (replacement of the cathode electrode 19) will be described in detail below with reference to FIG. 4. In step S41, the controller CNT stops the supply of electric power to the electron gun EG in the electron gun chamber 2. In step S42, the controller CNT blocks the supply of electric power to the electron gun EG′ for conditioning in the conditioning chamber 1.

In step S43, the controller CNT opens a valve 20 disposed in the portion in which the electron gun chamber 2 is connected to the removal chamber 4. In step S44, the controller CNT causes the driving mechanism 21 to move the used cathode electrode 19 from the electron gun chamber 2 into the removal chamber 4. In step S45, the controller CNT closes the valve 20. In step S46, the controller CNT opens the removal chamber 4 to the atmosphere. In step S47, the controller CNT opens a valve 6 on the atmospheric side of the removal chamber 4. In step S47, the used cathode electrode 19 is removed from the removal chamber 4.

In step S48, the controller CNT opens a valve 22 disposed in the portion in which the electron gun chamber 2 is connected to the conditioning chamber 1. In step S49, the controller CNT causes the driving mechanism 21 to move the spare cathode electrode 25 from the conditioning chamber 1 into the electron gun chamber 2 and install it into an electron gun EG. In step S50, the controller CNT closes the valve 22. In step S51, the controller CNT performs inspection (for example, an electrode continuity test) of the spare cathode electrode 25 installed in the electron gun EG. In step S52, the controller CNT aligns the spare cathode electrode 25.

As described above, the time required for vacuuming, burning, and conditioning can be shortened by providing a conditioning chamber and performing conditioning (burning and conditioning) of a spare cathode electrode to be used next. This makes it possible to improve the throughput.

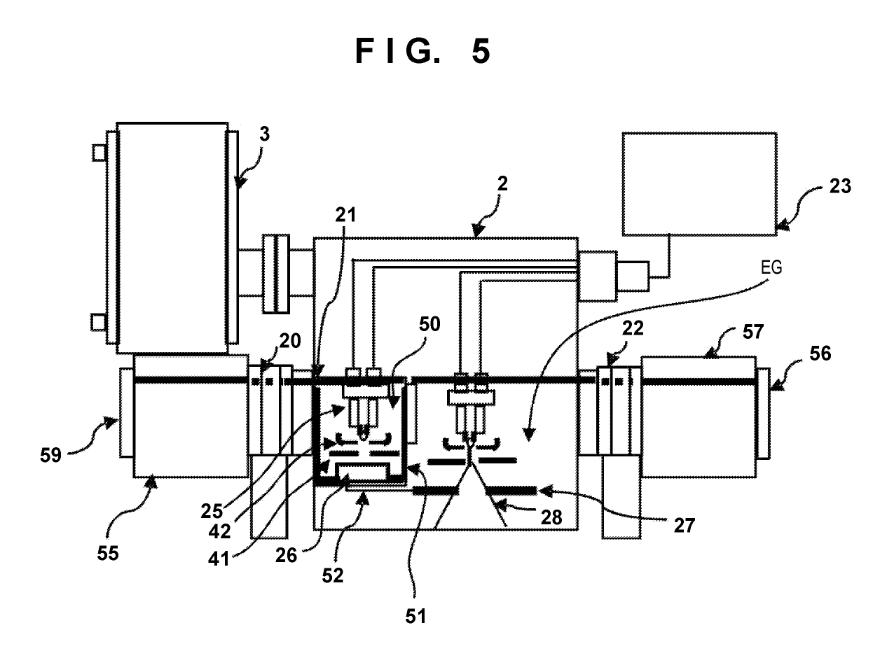

The configuration of an electron beam drawing apparatus 100 according to the second embodiment of the present invention will be described with reference to FIG. 5. Note that details which are not particularly referred to herein can be the same as in the first embodiment. A device chamber 7, projection system chamber 8, and stage chamber 9 are not shown in FIG. 5. In the second embodiment, a conditioning chamber 1 is disposed in an electron gun chamber 2. To heat a spare cathode electrode 25 in the conditioning chamber 1, heat generated by a blocking electrode 27 which blocks an unnecessary component of an electron beam 28 is utilized. A heat insulator 51 is provided in the conditioning chamber 1 to prevent heat from the conditioning chamber 1 from adversely affecting any component such as the electron gun EG in the electron gun chamber 2.

Although an example in which among a cathode electrode, a Wehnelt electrode, and an anode electrode, the cathode electrode is replaced has been given above, the present invention is also applicable to replacement of the other electrodes. Also, the configuration of an electron gun is not limited to such an example, and various configurations can be adopted.

A method of manufacturing a device according to an embodiment of the present invention is suitable for manufacturing a device such as a semiconductor device or a reticle. This method can include a step of drawing a pattern on a substrate, coated with a photosensitive agent, using the above-mentioned electron beam drawing apparatus, and a step of developing the substrate. This method can also include subsequent known steps (for example, oxidation, film formation, vapor deposition, doping, planarization, etching, resist removal, dicing, bonding, and packaging).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-104740, filed May 9, 2011, which is hereby incorporated by reference herein in its entirety.

What is claimed is:

1. An electron beam drawing apparatus which includes an electron gun, and performs drawing on a substrate with an electron beam emitted by the electron gun, the apparatus comprising:
a conditioning chamber configured to perform conditioning of a spare electrode that is a spare for an electrode which constitutes the electron gun; and
a driving mechanism configured to remove a used electrode from the electron gun, and to install, into the electron gun, the spare electrode having been subjected to the conditioning,
wherein the conditioning includes supplying of electric power to the spare electrode.

2. The apparatus according to claim 1, wherein the conditioning includes heating of the spare electrode.

3. The apparatus according to claim 2, further comprising
an electron optical element configured to block the electron beam emitted by the electron gun,
wherein the heating heats the spare electrode with heat from the electron optical element by which the electron beam has been blocked.

4. The apparatus according to claim 1, further comprising another electron gun for the conditioning, wherein the conditioning is performed with the spare electrode installed in the other electron gun.

5. The apparatus according to claim 1, further comprising
an inspection unit disposed in the conditioning chamber and configured to inspect the spare electrode,
wherein it is determined using the inspection unit whether the conditioning is completed.

6. The apparatus according to claim 1, further comprising another chamber configured to accommodate the electron gun, wherein the conditioning chamber is disposed outside the other chamber and connected to the other chamber.

7. The apparatus according to claim 1, further comprising another chamber configured to accommodate the electron gun, wherein the conditioning chamber is disposed in the other chamber.

8. The apparatus according to claim 1, wherein the spare electrode includes a cathode electrode.

9. A method of manufacturing a device, the method comprising:
performing drawing on a substrate using an electron beam drawing apparatus; and
developing the substrate on which the drawing has been performed,
wherein the electron beam drawing apparatus includes an electron gun, and performs drawing on the substrate with an electron beam emitted by the electron gun, the apparatus comprises
a conditioning chamber configured to perform conditioning of a spare electrode that is a spare for an electrode which constitutes the electron gun; and
a driving mechanism configured to remove a used electrode from the electron gun, and to install, into the electron gun, the spare electrode having been subjected to the conditioning,
wherein the conditioning includes supplying of electric power to the spare electrode.
